(19) United States
(12) Patent Application Publication
(10) Pub. No.: US 2025/0362707 A1
(43) Pub. Date: Nov. 27, 2025

(54) TILED IN-MEMORY COMPUTATION PROCESSING SYSTEM WITH RANDOMIZED CLOCK STAGGERING AND OUTPUT BINDING

(71) Applicant: STMicroelectronics International N.V., Geneva (CH)

(72) Inventors: Nitin CHAWLA, Noida (IN); Manuj AYODHYAWASI, Noida (IN); Harsh RAWAT, Faridabad (IN)

(73) Assignee: STMicroelectronics International N.V., Geneva (CH)

(21) Appl. No.: 19/201,137

(22) Filed: May 7, 2025

Related U.S. Application Data
(60) Provisional application No. 63/650,202, filed on May 21, 2024.

(51) Int. Cl. G06F 1/06

(52) U.S. Cl. CPC G06F 1/06

(57) ABSTRACT

First and second in-memory computation (IMC) processing tiles store computational weight data for in-memory computation operations executed in response to feature data. The first IMC processing tile is clocked by a first clock signal to control execution of the in-memory computation operation, and the second IMC processing tile is clocked by a second clock signal to control execution of the in-memory computation operation. A clock tree generates the first and second clock signals. In response to a random number, the clock tree applies a randomized stagger to timing of the first and second clock signals. A binding circuit matches and binds the first and second computation outputs. The binding circuit, in response to the random number, accounts for timing offset between the first and second computation outputs due to the randomized stagger to timing of the first and second clock signals.

### CROSS-REFERENCE TO RELATED APPLICATIONS

This application claims priority from United States Provisional Application for Patent No. 63/650,202, filed May 21, 2024, which is incorporated herein by reference.

### TECHNICAL FIELD

Embodiments herein relate to an in-memory computation processing system including a plurality of in-memory computation processing tiles and, in particular, to the use of a randomized clock staggering and output binding for those in-memory computation processing tiles.

### BACKGROUND

An in-memory computation (IMC) processing tile stores information in the bit cells of a memory array and performs calculations at the bit cell level. An example of a calculation performed by an IMC processing tile is a multiply and accumulate (MAC) operation where an input array of numbers (also referred to as the feature or coefficient data (FD)) are multiplied by an array of computational weights (WD) stored in the memory and the products are added together to produce an output array of numbers (CMP).

By performing these calculations at the bit cell level in the memory, the IMC processing tile does not need to move data back and forth between a memory device and a computing device. Thus, the limitations associated with data transfer bandwidth between devices are obviated and the computation can be performed with lower power consumption.

An IMC processing tile includes a circuit that utilizes a memory array formed by a plurality of memory cells arranged in a matrix format. Each memory cell is programmed to store a bit of the computational weight data WD (also referred to as kernel data) for an in-memory computation operation. In an implementation, each bit of the computational weight data has either a logic “1” value or a logic “0” value which is represented, for example, by a logic state programmed into the memory cell.

It is often the case that the computational weight data is highly valuable and proprietary information. Persons of bad intent often try to extract the computational weight data using an extraction technique known in the art as a side channel attack which evaluates power consumption during operation of a processing system including one or more IMC processing tiles. In implementations where the weights remain stationary for long duration of operations and have a specific sparsity attached thereto, the computational weight data is even more susceptible to the side channel attack. There is a need in the art to provide the processing system with protections against side channel attack efforts to decode the details of (sparse and stationary, for example) computational weight data stored in the memory array of each included IMC processing tile.

### SUMMARY

In an embodiment, a circuit comprises: a first in-memory computation (IMC) processing tile configured to store first computational weight data for an in-memory computation operation and configured to receive first feature data for that in-memory computation operation and receive a first clock signal, the first IMC processing tile generating a first computation output in response to execution of the in-memory computation operation; a second IMC processing tile configured to store second computational weight data for an in-memory computation operation and configured to receive second feature data for that in-memory computation operation and receive a second clock signal, the second IMC processing tile generating a second computation output in response to execution of the in-memory computation operation; a clock tree configured to generate the first and second clock signals, wherein the clock tree, in response to a random number, applies a randomized stagger to timing of the first and second clock signals; and a binding circuit configured to match and bind the first and second computation outputs, wherein the binding circuit, in response to the random number, accounts for timing offset between the first and second computation outputs due to the randomized stagger to timing of the first and second clock signals.

In an embodiment, a method comprises: storing first computational weight data for an in-memory computation operation in a first in-memory computation (IMC) processing tile; storing second computational weight data for an in-memory computation operation in a second IMC processing tile; applying first feature data for the in-memory computation operation to the first IMC processing tile; applying second feature data for the in-memory computation operation to the second IMC processing tile; clocking the first IMC processing tile with a first clock signal to control execution of the in-memory computation operation by the first IMC processing tile to produce a first computation output; clocking the second IMC processing tile with a second clock signal to control execution of the in-memory computation operation by the second IMC processing tile to produce a second computation output; generating the first and second clock signals to have a randomized stagger in timing controlled by a random number; and binding, in response to the random number, the first and second computation outputs, wherein binding includes matching to account for timing offsets between the first and second computation outputs due to the randomized stagger of the first and second clock signals.

In an embodiment, a circuit comprises: a first in-memory computation (IMC) processing tile group, wherein said first IMC processing tile group includes a first plurality of IMC processing tiles, each of the first plurality of IMC processing tiles configured to store computational weight data for an in-memory computation operation and configured to receive feature data for that in-memory computation operation, wherein the first plurality of IMC processing tiles of the first IMC processing tile group receive a first clock signal, the first plurality of IMC processing tiles generating first computation outputs in response to execution of the in-memory computation operation, the first IMC processing tile group further including a first binding circuit configured to bind the first computation outputs to generate a first tile group computation output; a second IMC processing tile group, wherein said second IMC processing tile group includes a second plurality of IMC processing tiles, each of the second plurality of IMC processing tiles configured to store computational weight data for an in-memory computation operation and configured to receive feature data for that in-memory computation operation, wherein the second plurality of IMC processing tiles of the second IMC processing tile group receive a second clock signal, the second plurality of IMC processing tiles generating second computation outputs in response to execution of the in-memory computation operation, the second IMC processing tile group further including a second binding circuit configured to bind the second computation outputs to generate a second tile group computation output; a clock tree configured to generate the first and second clock signals, wherein the clock tree, in response to a random number, applies a randomized stagger to timing of the first and second clock signals; and a third binding circuit configured to match and bind the first and second tile group computation outputs, wherein the third binding circuit, in response to the random number, accounts for timing offset between the first and second tile group computation outputs due to the randomized stagger to timing of the first and second clock signals.

In an embodiment, a method comprising: storing computational weight data for in-memory computation operations in a first plurality of in-memory computation (IMC) processing tiles arranged to form a first IMC processing tile group; storing computational weight data for in-memory computation operations in a second plurality of IMC processing tiles arranged to form a second IMC processing tile group; applying feature data for the in-memory computation operations to the first plurality of IMC processing tiles; applying feature data for the in-memory computation operations to the second plurality of IMC processing tiles; clocking the first plurality of IMC processing tiles within the first IMC processing tile group with a first clock signal to control execution of the in-memory computation operations by the first plurality of IMC processing tiles to produce first computation outputs; binding the first computation outputs to generate a first tile group computation output; clocking the second plurality of IMC processing tiles within the second IMC processing tile group with a second clock signal to control execution of the in-memory computation operations by the second plurality of IMC processing tiles to produce second computation outputs; binding the second computation outputs to generate a second tile group computation output; generating the first and second clock signals to have a randomized stagger in timing controlled by a random number; and binding, in response to the random number, the first and second tile group computation outputs, wherein binding includes matching to account for timing offsets between the first and second tile group computation outputs due to the randomized stagger of the first and second clock signals.

In an embodiment, in-memory computation (IMC) processing tiles are configured to store computational weight data for in-memory computation operations. A clock tree is configured to generate clock signals for application to the IMC processing tiles for controlling the execution of the in-memory computation operations. The clock tree, in response to a random number, applies a randomized stagger to the timing of clock signals. The randomized stagger in timing that is applied to tile processing operations produces a randomization to the power pattern for the in-memory compute system processing operation even in the instance where the stored computational weight data is stationary and exhibits sparsity.

### BRIEF DESCRIPTION OF THE DRAWINGS

For a better understanding of the embodiments, reference will now be made by way of example only to the accompanying figures in which:

FIG. 1 is a block diagram of an in-memory computation processing system including a plurality of in-memory computation processing tiles;

FIG. 2 is a timing diagram illustrating an example operation of the processing system of FIG. 1;

FIG. 3 is a timing diagram illustrating an example operation of the processing system of FIG. 1;

FIG. 4 is a schematic diagram of an analog in-memory computation tile for use in the processing system of FIG. 1;

FIG. 5 is a circuit diagram of a 6T static random access memory (SRAM) cell;

FIG. 6 is a circuit diagram of an 8T SRAM cell;

FIG. 7 is a schematic diagram of a digital in-memory computation tile for use in the processing system of FIG. 1;

FIG. 8 is a block diagram of an in-memory computation processing system including a plurality of in-memory computation processing tile groups;

FIG. 9 shows a block diagram for a tile group;

FIG. 10 is a timing diagram illustrating an example operation of the processing system of FIG. 8; and

FIG. 11 is a timing diagram illustrating an example operation of the processing system of FIG. 8.

### DETAILED DESCRIPTION OF THE DRAWINGS

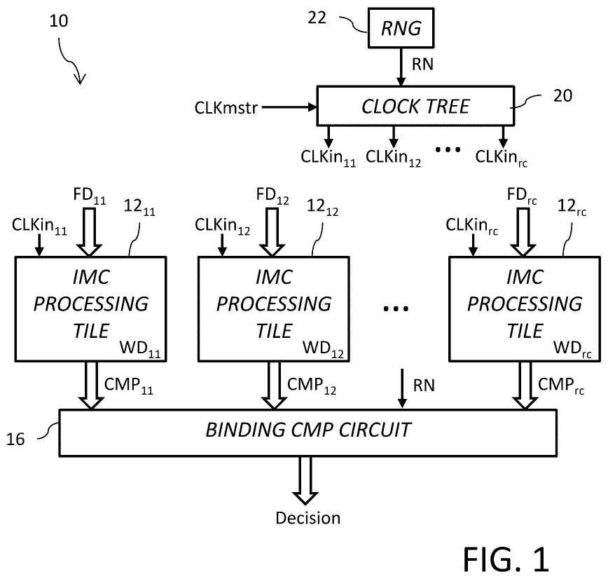

Reference is now made to FIG. 1 which shows a block diagram of an in-memory computation processing system 10. The processing system 10 includes a plurality of in-memory computation (IMC) processing tiles 12. The IMC processing tiles 12 may, for example, be arranged in an array format having one or more tile rows and a plurality of tile columns (or a plurality of tile rows and one or more tile columns). FIG. 1 illustrates, by example only, an arrangement of IMC processing tiles 12 for the processing system 10 to include a single tile row including a plurality of IMC processing tiles 12, where each IMC processing tile 12 is located in a tile column.

The in-memory computation processing operation performed by each IMC processing tile 12 is dependent on, at least, computational weight or kernel data (WD) stored in a memory array of the IMC processing tile 12, feature or coefficient data (FD) input to the IMC processing tile 12, and a clock signal CLKin input to the IMC processing tile 12. One or more pulses in the pulse train of the clock signal CLKin controls timing for the in-memory computation processing operation at each IMC processing tile 12 to access the computational weight or kernel data (WD) and multiply the accessed computational weight or kernel data (WD) by the feature or coefficient data (FD) to generate data for a computation output (CMP) of the multiply and accumulate (MAC) operation.

In the architectural context shown in FIG. 1, the index r designates the tile row and the index c designates the tile column. Thus, computational weight or kernel data WD_{rc} generally designates the stored data for the in-memory computation processing operation in the memory array for the IMC processing tile 12_{rc} located within the processing system 10 at tile row r and tile column c. Furthermore, the feature or coefficient data FD_{rc} generally designates the input data for the in-memory computation processing operation applied to the IMC processing tile 12_{rc} located within the processing system 10 at tile row r and tile column c. Also, the tile computation output CMP_{rc} generally designates the output data for the in-memory computation processing operation produced by the IMC processing tile 12_{rc} located within the processing system 10 at tile row r and tile column c. Still further, clock signal CLKin_{rc} generally designates the input clock applied to the IMC processing tile 12_{rc} located within the processing system 10 at tile row r and tile column c.

The processing system 10 further includes an output binding circuit 16 configured to receive the tile computation output CMP_{rc} from the in-memory computation processing operation performed by each IMC processing tile 12_{rc} and bind the received tile computation data to generate a decision output (Decision) for the in-memory computation operation. In this context, each IMC processing tile 12_{rc} is configured to generate a partial computational output that contributes to a final result (for example, the decision). This final output might, for example, represent a computational value for a layer or a specific sub-tensor geometry. Depending on the graph topology through which the data is processed, these IMC processing tiles 12_{rc} may be arranged in a sequence or aligned in parallel configurations. The operation performed by the binding circuit 16 among the IMC processing tiles 12_{rc} represent groups of stall domains and co-scheduled execution pipelines. The various outputs of the IMC processing tiles 12_{rc} in the performed operations, notwithstanding the timing offsets, are matched to and bound to each other through the binding operation performed by the binding circuit 16.

The various clock signals CLKin_{rc} applied to the corresponding IMC processing tiles 12_{rc} are generated by a clock tree circuit 20 from a master clock signal CLKmstr. There is not, however, a fixed (i.e., non-changing) timing relationship for the various clock signals CLKin_{rc}. The clock tree circuit 20 receives a random number (RN) generated by a random number generator (RNG) circuit 22. In response to the received random number RN, the clock tree circuit 20 applies, for example in connection with execution of each in-memory computation operation, a randomized stagger to the timing relationship for the various clock signals CLKin_{rc}. This randomized staggering may, for example, be implemented by applying phase shift(s) to one or more randomly selected ones of the various clock signals CLKin_{rc}. This randomized staggering may, for example, be implemented by skipping a clock pulse in one or more randomly selected ones of the various clock signals CLKin_{rc}. This randomized staggering may, for example, be implemented by adding a clock pulse in one or more randomly selected ones of the various clock signals CLKin_{rc}.

As a result of the applied randomized stagger to the timing relationship for the various clock signals CLKin_{rc}, there will be a corresponding randomized stagger present in the timing for generation of the tile computation outputs CMP_{rc} by the IMC processing tiles 12_{rc}. To account for timing offsets introduced by the randomized stagger of the timing relationships, and ensure proper matched binding of the received computation data to generate a decision output (Decision) for the in-memory computation operation, the random number RN is also applied to the output binding circuit 16. Responsive to received random number RN, the output binding circuit 16 can apply a corresponding randomized stagger to the timing process for collecting, matching and binding the computation outputs CMP_{rc} by the IMC processing tiles 12_{rc}. In effect, the output binding circuit 16 will properly match and bind the received computation data for corresponding, but time offset, in-memory computation operations performed by the IMC processing tiles 12_{rc}.

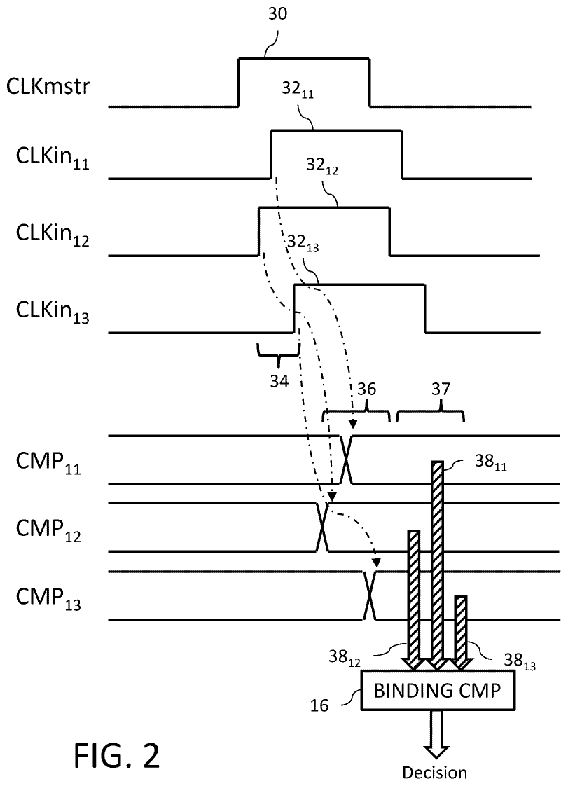

The foregoing may be better understood by considering a specific example with the timing diagram shown by FIG. 2. For a given pulse 30 of the master clock signal CLKmstr, the clock tree circuit 20, in response to the random number (RN) generated by the random number generator (RNG) circuit 22, generates a corresponding pulse 32₁₁ for the clock signal CLKin₁₁ applied to the IMC processing tile 12₁₁, a corresponding pulse 32₁₂ for the clock signal CLKin₁₂ applied to the IMC processing tile 12₁₂, and a corresponding pulse 32₁₃ for the clock signal CLKin₁₃ applied to the IMC processing tile 12₁₃. Note that there is randomized stagger (reference 34) present in the timing of the leading edges of the pulses 32₁₁, 32₁₂ and 32₁₃, where that randomized stagger is dependent on the generated random number (RN) and implemented as a phase shift. Because of this, there will be a corresponding randomized stagger 36 present in the timing for the performance of the in-memory computation operation in each IMC processing tiles 12_{rc} (the in-memory compute operation performance indicated by the dash-dot arrow) along with a corresponding randomized stagger 37 present in the timing for the presentation of the computation outputs CMP₁₁, CMP₁₂ and CMP₁₃ for the in-memory computation operations performed by the IMC processing tiles 12₁₁, 12₁₂, and 12₁₃. Using the random number (RN) generated by the random number generator (RNG) circuit 22, the output binding circuit 16 will control the timing for receiving 38₁₁, 38₁₂ and 38₁₃ the matched computation outputs CMP₁₁, CMP₁₂ and CMP₁₃, respectively, the IMC processing tiles 12₁₁, 12₁₂, and 12₁₃ for proper data matching and binding to produce the decision output (Decision). In this way, the computation outputs CMP₁₁, CMP₁₂ and CMP₁₃ which are generated in response to the initial pulse 30 of the master clock signal CLKmstr are correctly matched to each other and bound for processing to produce the decision output (Decision).

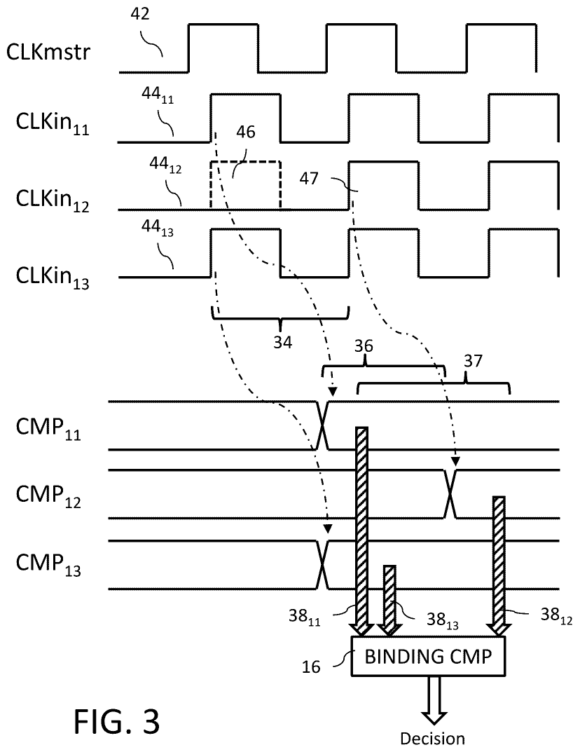

As another example, consider the timing diagram shown by FIG. 3. The clock tree circuit 20 receives the train of pulses 42 for the master clock signal CLKmstr and outputs a train of pulses 44 for each of the clock signals CLKin_{rc}. However, the clock tree circuit 20, in response to the random number (RN) generated by the random number generator (RNG) circuit 22, will randomly suppress (i.e., skip) a clock pulse in certain one(s) of the clock signals CLKin_{rc} (as indicated by reference 46). In the example where the clock tree circuit 20 generates clock signal CLKin₁₁ for application to the IMC processing tile 12₁₁, clock signal CLKin₁₂ for application to the IMC processing tile 12₁₂, and clock signal CLKin₁₃ for application to the IMC processing tile 12₁₃, the logic state of a certain bit of the random number (RN), or the logic state of certain bit of a signal generated by decoding the random number (RN), will specify whether the clock tree circuit 20 should selectively suppress (i.e., skip) an included clock pulse. In this example case, there is a random suppression (i.e., skipping) of the pulse 46 in the clock signal CLKin₁₂ for application to the IMC processing tile 12₁₂ to introduce a timing offset (or stagger) 34 of the leading edges of the clock pulses which control timing for execution of the in-memory computation operation. Because of this, there will be a corresponding timing offset (or stagger) 36 in performance of the in-memory computation operation by IMC processing tile 12₁₂ relative to performance of the in-memory computation operation by IMC processing tiles 12₁₁ and 12₁₃ (because IMC processing tile 12₁₂ will perform the in-memory computation operation in response to the pulse 47 subsequent to the skipped pulse 46), where the in-memory compute operation performances are indicated by the dash-dot arrows. As a result, there will be a corresponding timing offset 37 in the presentation of the computation output CMP₁₂ relative to the computation outputs CMP₁₁ and CMP₁₃ for the in-memory computation operations performed by the IMC processing tiles 12₁₁, 12₁₂, and 12₁₃. Using the random number (RN) generated by the random number generator (RNG) circuit 22, the output binding circuit 16 will control the timing for receiving 38₁₁, 38₁₂ and 38₁₃ the matching computation outputs CMP₁₁, CMP₁₂ and CMP₁₃, respectively, from the IMC processing tiles 12₁₁, 12₁₂, and 12₁₃ for proper data matching and binding to produce the decision output (Decision). In this way, the computation outputs CMP₁₁, CMP₁₂ and CMP₁₃ which are generated in response to the initial pulse 30 of the master clock signal CLKmstr are correctly matched to each other bound for processing to produce the decision output (Decision).

It will be recognized that the operation described herein which introduces a randomized staggering of the timing for controlling the in-memory computation operations performed by the IMC processing tiles 12₁₁ provides a measure of protection that makes it more difficult for a power-based side channel attack to succeed in discerning the stored computational weight data (WD). Indeed, the randomized stagger (reference 34) and relative timing offsets of the leading edges of the pulses for the clock signals CLKin_{rc} will result in a randomized power waveform for the processing system 10 in connection with the processes for accessing the computational weight or kernel data (WD) and multiplying the accessed computational weight or kernel data (WD) by the feature or coefficient data (FD) to generate data for the tile computation outputs (CMP). The randomized stagger or offset (reference 34) applied to the clock signals CLKin_{rc} minimizes electromagnetic interference (EMI) and manages clock transient current consumption. This reduces the likelihood of successfully processing the current profile of the system to recover the stored weight data (which may, for example, be stationary and exhibit sparsity).

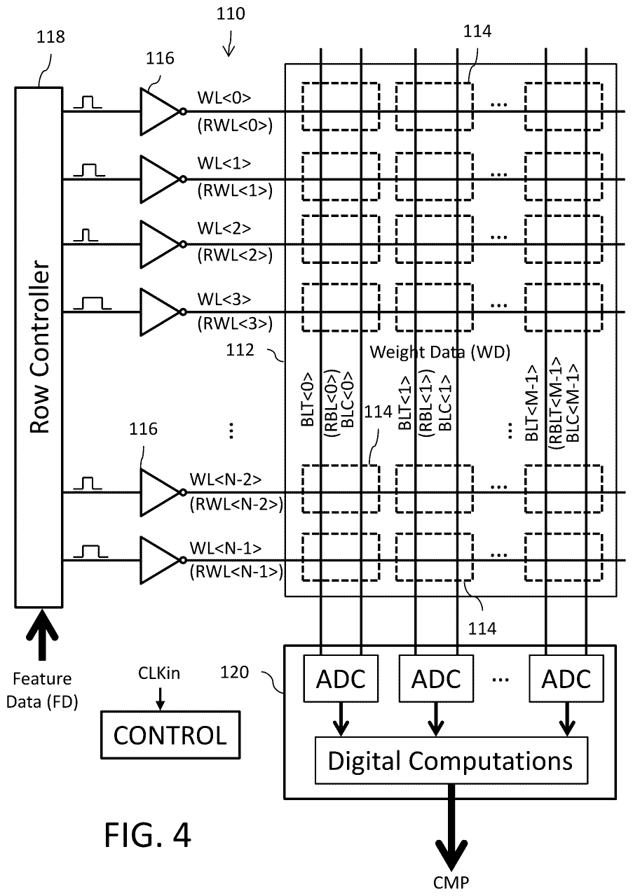

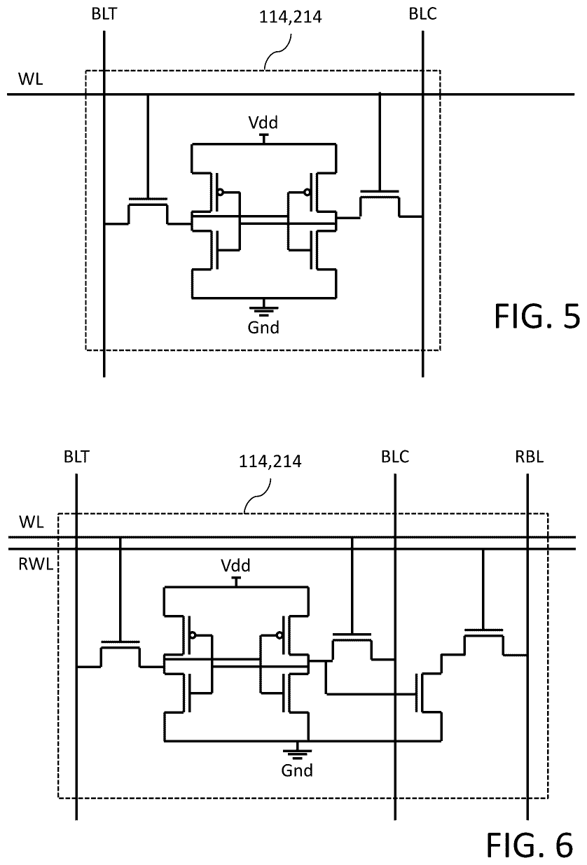

Reference is now made to FIG. 4 which shows a schematic diagram of an analog IMC processing tile 110 which could be used, for example, as one or more of the IMC processing tiles 12_{rc} in the system 10 of FIG. 1. The tile 110 utilizes a memory circuit including a static random access memory (SRAM) array 112 formed by standard 6T SRAM memory cells 114 (see, FIG. 5) arranged in a matrix format having N rows and M columns. As an alternative, a standard 8T memory cell (see, FIG. 6) or an SRAM with a similar functionality and topology could instead be used. Each memory cell 114 is programmed to store a bit of a computational weight or kernel data (WD) for an in-memory computation operation. In this context, the in-memory computation operation is understood to be a form of a high dimensional Matrix Vector Multiplication (MVM) supporting multi-bit weights that are stored in multiple bit cells of the memory. The group of bit cells (in the case of a multibit weight) can be considered as a virtual synaptic element. Each bit of the computational weight has either a logic “1” or a logic “0” value.

Each SRAM cell 114 includes a word line WL and a pair of complementary bit lines BLT and BLC. The 8T-type SRAM cell would additionally include a read word line RWL and a read bit line RBL. The cells 114 in a common row of the matrix are connected to each other through a common word line WL (and through the common read word line RWL in the 8T-type implementation). The cells 114 in a common column of the matrix are connected to each other through a common pair of complementary bit lines BLT and BLC (and through the common read bit line RBL in the 8T-type implementation). Each word line WL, RWL is driven by a word line driver circuit 116 which may be implemented as a CMOS driver circuit (for example, a series connected p-channel and n-channel MOSFET transistor pair forming a logic inverter circuit). The word line signals applied to the word lines, and driven by the word line driver circuits 116, are generated from feature data input to the in-memory computation tile 110 and controlled by a row controller circuit 118. A column processing circuit 120 senses the analog signals on the pairs of complementary bit lines BLT and BLC (and/or on the read bit line RBL) for the M columns, converts the analog signals to digital signals, performs digital calculations on the digital signals and generates a computation output CMP for the in-memory computation operation.

It will be understood that the tile 110 may instead use a different type of memory cell, for example, any form of a bit cell, storage element or synaptic element.

Although not explicitly shown in FIG. 4, it will be understood that the tile 110 further includes conventional row decode, column decode, and read-write circuits known to those skilled in the art for use in connection with writing bits of data (for example, the computational weight data) to, and reading bits of data from, the SRAM cells 114 of the memory array 112. This operation is referred to as a conventional memory access mode and is distinguished from the analog in-memory compute operation discussed above.

The row controller circuit 118 receives the feature data (FD) for the in-memory computation operation and in response thereto performs the function of selecting which ones of the word lines WL<0> to WL<N−1> (or read word lines RWL<0> to RWL<N−1>) are to be simultaneously accessed (or actuated) in parallel during an analog in-memory computation operation, and further functions to control application of pulsed signals to the word lines in accordance with that in-memory computation operation. FIG. 4 illustrates, by way of example only, the simultaneous actuation of all N word lines with the pulsed word line signals, it being understood that in-memory computation operations may instead utilize a simultaneous actuation of fewer than all rows of the SRAM array. The analog signals on a given pair of complementary bit lines BLT and BLC (or analog signal on the read bit line RBL in the 8T-type implementation) are dependent on the logic state of the bits of the computational weight stored in the memory cells 114 of the corresponding column and the width(s) of the pulsed word line signals applied to those memory cells 114.

A control circuit controls performance of the analog in-memory computation operation responsive to the received clock signal CLKin.

The implementation illustrated in FIG. 4 shows an example in the form of a pulse width modulation (PWM) for the applied word line signals for the in-memory computation operation dependent on the received feature data. The use of PWM or period pulse modulation (PTM) for the applied word line signals is a common technique used for the in-memory computation operation based on the linearity of the vector for the multiply-accumulation (MAC) operation. The pulsed word line signal format can be further evolved as an encoded pulse train to manage block sparsity of the feature data of the in-memory computation operation. It is accordingly recognized that an arbitrary set of encoding schemes for the applied word line signals can be used when simultaneously driving multiple word lines. Furthermore, in a simpler implementation, it will be understood that all applied word line signals in the simultaneous actuation may instead have a same pulse width.

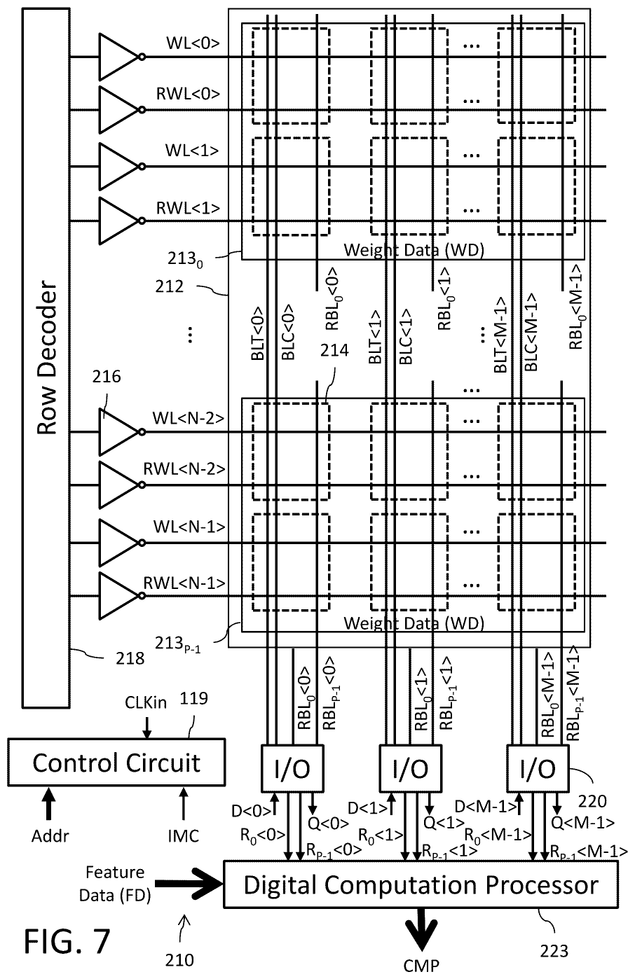

Reference is now made to FIG. 7 which shows a block diagram of a digital IMC processing tile 210 which could be used, for example, as one or more of the IMC processing tiles 12_{rc} in the system 10 of FIG. 1. The tile 210 is implemented using a memory circuit which includes a static random access memory (SRAM) array 212 formed by a plurality of SRAM memory cells 214 arranged in a matrix format having N rows and M columns. Each memory cell 214 is programmed to store a bit of data. To support digital in-memory computation processing, the stored data in the memory array 212 comprises computational weight or kernel data (WD). In this context, the digital in-memory compute operation is understood to be a form of a high dimensional Matrix Vector Multiplication (MVM) supporting multi-bit weights that are stored in multiple bit cells of the memory. The group of bit cells (in the case of a multibit weight) can be considered as a virtual synaptic element. Each bit of data stored in the memory array, whether user data or weight data, has either a logic “1” or a logic “0” value.

Each SRAM memory cell 214 may comprise a 6T-type memory cell as shown in FIG. 5. As an alternative, a standard 8T memory cell (see, FIG. 6) or an SRAM with a similar functionality and topology could instead be used. It will be understood that the tile 210 may instead use a different type of memory cell, for example, any form of a bit cell, storage element or synaptic element producing a deterministic readout arranged in an array. As a non-limiting example, consideration is made for the use of a non-volatile memory (NVM) cell such as, for example, magnetoresistive RAM (MRAM) cell, Flash memory cell, phase change memory (PCM) cell or resistive RAM (RRAM) cell). In the following discussion, focus is made on the implementation using an 8T-type SRAM cell 214, but this is done by way of a non-limiting example, understanding that any suitable memory element could be used (e.g., a binary (two level) storage element or an m-ary (multi-level) storage element).

Each cell 214 includes a word line WL, a pair of complementary bit lines BLT and BLC, a read word line RWL and a read bit line RBL. The SRAM memory cells in a common row of the matrix are connected to each other through a common word line WL and through a common read word line RWL. Each of the word lines (WL and/or RWL) is driven by a word line driver circuit 216 with a word line signal generated by a row decoder circuit 218 during read and write operations. The SRAM memory cells in a common column of the matrix across the whole array 212 are connected to each other through a common pair of complementary (write) bit lines BLT and BLC. The array 212 is segmented into P sub-arrays 213₀ to 213_{P-1}. Each sub-array 213 includes M columns and N/P rows of memory cells 214. The SRAM memory cells in a common column of each sub-array 213 are connected to each other through a local read bit line RBL.

The P local read bit lines RBL₀<x> to RBL_{P-1}<x> from the sub-arrays 213 for the column x in the array 212 are coupled, along with the common pair of complementary bit lines BLT<x> and BLC<x> for the column x in the array 212, to a column input/output (I/O) circuit 220(x). Here, x=0 to M−1. A data input port (D) of the column I/O circuit 220 receives input data (user or weight data) to be written to an SRAM memory cell 214 in the column through the pair of complementary bit lines BLT, BLC in response to assertion of a word line signal in a conventional memory access mode of operation. A data output port (Q) of the column I/O circuit 220 generates output data read from an SRAM memory cell 214 in the column through the read bit line RBL in response to assertion of a read word line signal in the conventional memory access mode of operation. Additionally, the column I/O circuit 220 further includes P sub-array data output ports R₀ to R_{P-1} to generate output data read from a memory cell 214 on the local read bit line RBL of the corresponding sub-array 213₀ to 213_{P-1}, respectively, in response to the simultaneous assertion of a plurality of read word line signals (one per sub-array 213) in a digital in-memory compute mode of operation. A digital computation processing circuit 223 performs digital computations on the output data from the sub-array data output ports R as a function of received feature data (FD) and generates a computation output CMP for the in-memory computation operation. The processing circuit 223 can implement computation logic for the digital signal processing in a number of ways including: full support of Boolean operations (XOR, XNOR, NAND, NOR, etc.) and vector operations depending on system and application needs; accumulation pipeline operations where vector multiplication is supported within the memory; and matrix vector multiplication pipeline operations where output from the memory as one vector for the multiply and accumulate (MAC) function. It will be noted that the processing circuit 223 is an integral part of the digital in-memory computation circuit 210.

The computation logic for the digital signal processing performed by processing circuit 223 is closely integrated with the input/output circuits and the sub-array data output ports R₀ to R_{P-1} to support utilization of a wide (for example, P times) vector access. There are a number of figure of merit (FOM) benefits which accrue from this solution including: enabling multi-word access in a same cycle amortizes the common logic toggling power inside the SRAM when wide vector access occurs; the use of sub-arrays 213 can reduce bit line toggling power consumption (i.e., where P word lines are asserted in parallel to access P corresponding sub-arrays); support of both, with the opportunity to toggle between, the conventional memory access mode of operation and the digital in-memory compute mode of operation; and on/off current ratio on the same bitline improves which is a key concern when the circuitry is implemented using fully-depleted silicon-on-insulator (FDSOI) technology where forward body bias is aggressively used.

It will be noted that the tile 210 presents a conventional SRAM interface through the data input ports D and the data output ports Q in accordance with a conventional memory access mode of operation. In response to an applied memory address (Addr), the circuit supports read (via data output ports Q) and write (via data input ports D) access to a single row of memory cells 214 in the array 212 by the selected assertion of a single word line WL or RWL. The circuit further presents a sub-array processing interface through the sub-array data output ports R₀ to R_{P-1} in accordance with the digital in-memory computation mode of operation. In response to an applied memory address (Addr), the circuit supports simultaneous read (via data output ports R₀ to R_{P-1}) access to a single row of memory cells 214 in each of the sub-arrays 213₀ to 213_{P-1} by the simultaneous assertion of corresponding read word lines RWL. A single address can be decoded to select the plural word lines (one per sub-array 213) for assertion, or plural addresses can be decoded to select the plural word lines (one per sub-array 213) for assertion. The use plural sub-arrays 213 in this mode enables parallelism supporting very wide access for computation processing without sacrificing density. Advantageously, this digital in-memory compute mode of operation utilizes the resources of the conventional SRAM design with modified control, decoding and input/output circuits (as will be discussed herein in detail) to enable parallel access in the digital in-memory compute mode of operation with additional control to toggle between the conventional memory access mode of operation and the digital in-memory compute mode of operation as needed by the system application. This architecture brings parallelism with usage of the push rule bitcell thus enabling high density/compute density when configured for the in-memory compute mode of operation. Notwithstanding the foregoing, as noted above, usage of other bitcell types may instead be made.

A control circuit 219 controls mode operations of the circuitry within the tile 210 responsive to the logic state of a control signal IMC and the received clock signal CLKin. When the control signal IMC is in a first logic state (for example, logic low), the tile 210 operates in accordance with the conventional memory access mode of operation (for writing data from data input port D to the memory array or reading data from the memory array to data output port Q). Conversely, when the control signal IMC is in a second logic state (for example, logic high), the tile 210 operates in accordance with the digital in-memory compute mode of operation (for reading weight data from the memory array to the sub-array data output ports R).

When the tile 210 is operating in the conventional memory access mode of operation, and responsive to the clock signal CLKin, the row decoder circuit 218 decodes a received address (Addr), selectively actuates only one word line WL (during write) or one read word line RWL (during read) for the whole array 212 with a word line signal pulse to access a corresponding single one of the rows of memory cells 214. In write, logic states of the data at the input ports D are written by the column I/O circuits 220 through the pairs of complementary bit lines BLT, BLC to the single row of memory cells coupled to the accessed word line WL. In read, the logic states of the data stored in the single row of memory cells coupled to the accessed word line WL are output from the read bit lines RBL to the column I/O circuits 220 for output at the data output ports Q.

When the tile 210 is operating in the digital in-memory computation mode of operation, and responsive to the clock signal CLKin, the row decoder circuit 218 decodes a received address (Addr), selectively (and simultaneously) actuates one read word line RWL in each sub-array 213 in the memory array 212 with a word line signal pulse to access a corresponding row of memory cells 214 in each sub-array 213. The logic states of the weight data stored in the row of memory cells coupled to the accessed read word line RWL in each sub-array 213 are passed from the read bit lines RBL₀<x> to RBL_{P-1}<x> to the column I/O circuit 220 for output at the corresponding sub-array data output ports R₀ to R_{P-1}.

It will be noted that each sub-array 213 output can be considered as one subtensor/tensor for processing operations. Additionally, multiple sub-arrays 213 outputs can be grouped as a larger tensor. The grouping of sub-array outputs can be made across columns, across rows, or both. Such processing is supported through the configuration and operation of the processing circuit 223.

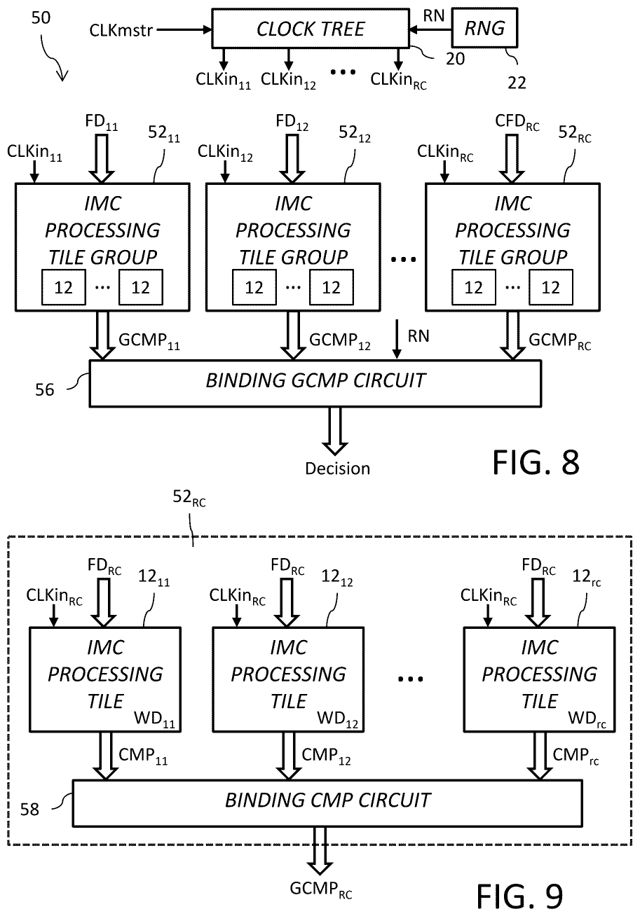

Reference is now made to FIG. 8 which shows a block diagram of an in-memory computation processing system 50. The processing system 50 includes a plurality of in-memory computation (IMC) processing tile groups 52. The IMC processing tile groups 52 may, for example, be arranged in an array format having one or more group rows and a plurality of group columns (or a plurality of group rows and one or more group columns). FIG. 8 illustrates, by example only, an arrangement of IMC processing tile groups 52 for the processing system 50 to include a single group row of a plurality of IMC processing tile groups 52, where each IMC processing tile group 52 is located in a group column. Each IMC processing tile group 52 includes one or more in-memory computation (IMC) processing tiles 12. The IMC processing tiles 12 within each IMC processing tile group 52 may, for example, be arranged in an array format having one or more tile rows and one or more columns. FIG. 8 illustrates, by example only, an arrangement of IMC processing tiles 12 within each tile group 52 to include a single tile row of a plurality of IMC processing tiles 12, where each IMC processing tile 12 is located in a tile column. An example implementation of a tile group 52 is shown in FIG. 9.

For reference, the implementation of the processing system 10 of FIG. 1 may be considered as a special case of the implementation of the processing system 50 of FIG. 8 where each tile group 52 includes only one IMC processing tile 12.

The in-memory computation processing operation performed by each IMC processing tile 12 is dependent on, at least, computational weight or kernel data (WD) stored in a memory array of the IMC processing tile 12, feature or coefficient data (FD) input to the IMC processing tile 12, and a clock signal CLKin input to the IMC processing tile 12. One or more pulses of the clock signal CLKin controls timing for the in-memory computation processing operation at each IMC processing tile 12 to access the computational weight or kernel data (WD) and multiply the accessed computational weight or kernel data (WD) by the feature or coefficient data (FD) to generate data for a computation output (CMP) of the multiply and accumulate (MAC) operation.

In the architectural context shown in FIGS. 8 and 9, the index r designates, within a given tile group 52, the tile row and the index c, within that given tile group 52, designates the tile column. Thus, computational weight or kernel data WD_{rc} generally designates the stored data for the in-memory computation processing operation in the memory array for the IMC processing tile 12_{rc} located within a given tile group 52 at tile row r and tile column c. Also, the computation output CMP_{rc} generally designates the output data for the in-memory computation processing operation produced by the IMC processing tile 12_{rc} located within the given tile group 52 at tile row r and tile column c. The index R designates the tile group row and the index C designates the tile group column. Furthermore, the feature or coefficient data FD_{RC} generally designates the input data for the in-memory computation processing operation applied to the IMC processing tiles 12_{rc} located within the tile group 52_{RC} at tile group row R and tile group column C. Still further, clock signal CLKin_{RC} generally designates the input clock applied to each of the IMC processing tiles 12_{rc} located within the tile group 52_{RC} at tile group row R and tile group column C. Also, the tile group computation output GCMP_{RC} generally designates the output data for the tile group 52_{RC} at tile group row R and tile group column C (that output data being generated by binding the computation output CMP_{rc} produced from the in-memory computation processing operations performed by the IMC processing tiles 12_{rc} located within the given tile group 52).

Each tile group 52 includes an output binding circuit 58 configured to receive the computation output CMP_{rc} from the in-memory computation processing operation performed by each IMC processing tile 12_{rc} within the tile group and bind the received data to generate a tile group computation output GCMP_{RC} for that tile group 52_{RC}. In this context, each IMC processing tile 12_{rc} is configured to generate a partial computational output that contributes to an intermediate result. This intermediate output might, for example, represent a computational value for a layer or a specific sub-tensor geometry. Depending on the graph topology through which the data is processed, these IMC processing tiles 12_{rc} may be arranged in a sequence or aligned in parallel configurations. The operation performed by the binding 58 among the IMC processing tiles 12_{rc} represent groups of stall domains and co-scheduled execution pipelines. The various outputs of the IMC processing tiles 12_{rc} in the performed operations are bound to each other through the binding 58. It will be noted that because the IMC processing tiles 12_{rc} within the tile group 52_{RC} receive the same clock signal CLKin_{RC}, the computation outputs CMP_{rc} are (substantially) simultaneously presented for binding by circuit 58.

The processing system 50 further includes an output binding circuit 56 configured to receive the tile group computation outputs GCMP_{RC} from the tile groups 52_{RC} and bind the received data to generate a decision output (Decision) for the in-memory computation operation. In this context, each tile group 52_{RC} is configured to generate a partial computational output that contributes to a final result (for example, the decision). This final output might, for example, represent a computational value for a layer or a specific sub-tensor geometry. Depending on the graph topology through which the data is processed, these tile groups 52_{RC} may be arranged in a sequence or aligned in parallel configurations. The operation performed by the binding 56 among the tile groups 52_{RC} represent groups of stall domains and co-scheduled execution pipelines. The various outputs of the tile groups 52_{RC} in the performed operations, notwithstanding the timing offsets, are bound to each other through the binding 56. Contrary to the timing operation for the IMC processing tiles 12_{rc} within the tile group 52_{RC}, each tile group 52_{RC} receives its respective clock signal CLKin_{RC} and thus the tile group computation outputs GCMP_{RC} may be presented for binding by circuit 56 at different time instants and this timing offset must be accounted for in order to correctly match and bind the tile group computation outputs GCMP_{RC}.

The various clock signals CLKin_{RC} applied to the corresponding tile groups 52_{RC} are generated by a clock tree circuit 20 from a master clock signal CLKmstr. There is not, however, a fixed (i.e., non-changing) timing relationship for the various clock signals CLKin_{RC}. The clock tree circuit 20 receives a random number (RN) generated by a random number generator (RNG) circuit 22. In response to the received random number RN, the clock tree circuit 20 applies, for example in connection with execution of each in-memory computation operation, a randomized stagger to the timing relationship for the various clock signals CLKin_{RC}. This randomized staggering may, for example, be implemented by applying a phase shift to one or more randomly selected ones of the various clock signals CLKin_{RC}. This randomized staggering may, for example, be implemented by skipping a clock pulse in one or more randomly selected ones of the various clock signals CLKin_{RC}. This randomized staggering may, for example, be implemented by adding a clock pulse in one or more randomly selected ones of the various clock signals CLKin_{RC}.

As a result of the applied randomized stagger to the timing relationship for the various clock signals CLKin_{RC}, there will be a corresponding randomized stagger present in the timing for generation of the tile group computation outputs GCMP_{RC} by the tile groups 52_{RC}. To account for this, and ensure proper matching and binding of the received data to generate a decision output (Decision) for the in-memory computation operation, the random number RN is also applied to the output binding circuit 56. Responsive to received random number RN, the output binding circuit 56 can apply a corresponding randomized stagger to the timing process for collecting and matching the tile group computation outputs GCMP_{RC} from the tile groups 52_{RC}.

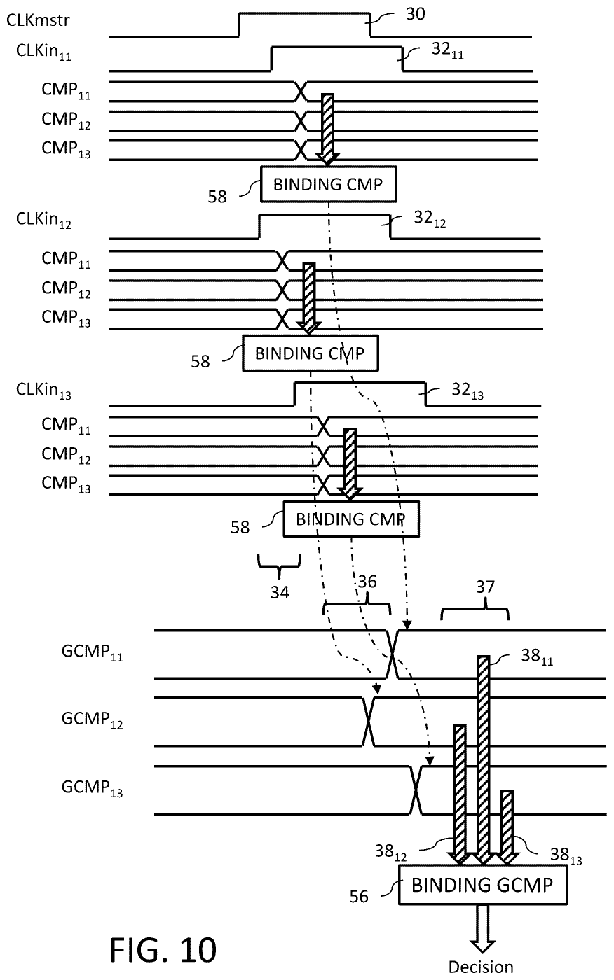

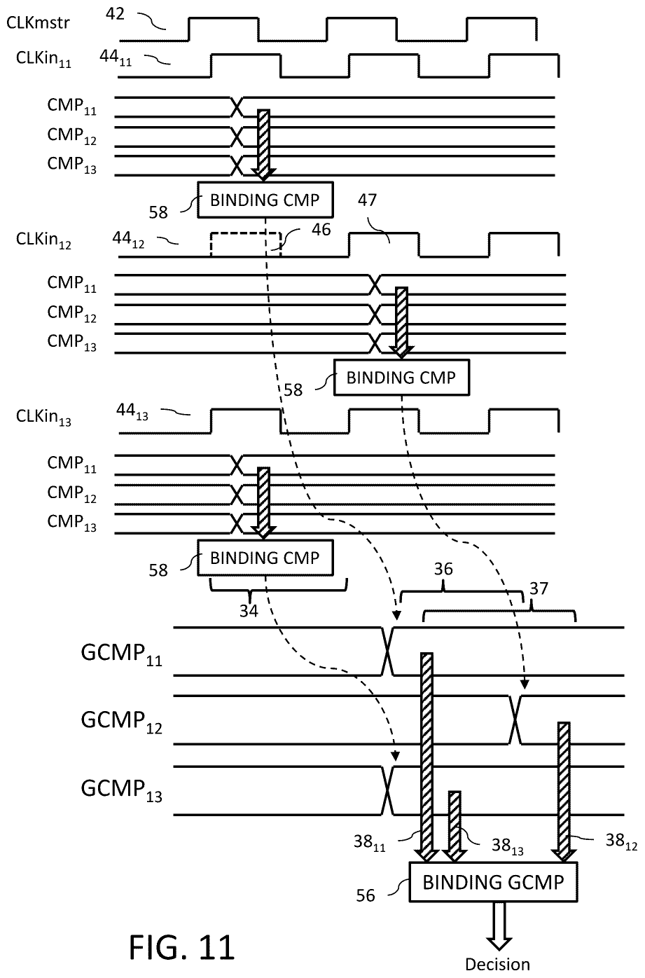

Operation of the system 50 in FIGS. 8 and 9 is analogous to the operation of the system 10 in FIG. 1 as shown by the timing diagrams of FIGS. 2 and 3. The main difference, as shown by the timing diagrams of FIGS. 10 and 11, is that the staggers (offsets) 34, 36 and 37 apply instead to the overall processing operations of the tile groups 52_{RC} and the matching and binding of the tile group computation outputs GCMP_{RC} as indicated by the dashed arrows.

United States Patent Application Publication Nos. 2024/0071439 and 2024/0112728 are incorporated herein by reference.

The foregoing description has provided by way of exemplary and non-limiting examples a full and informative description of the exemplary embodiment of this invention. However, various modifications and adaptations may become apparent to those skilled in the relevant arts in view of the foregoing description, when read in conjunction with the accompanying drawings and the appended claims. However, all such and similar modifications of the teachings of this invention will still fall within the scope of this invention as defined in the appended claims.

What is claimed is:

1. A circuit, comprising:
a first in-memory computation (IMC) processing tile configured to store first computational weight data for an in-memory computation operation and configured to receive first feature data for that in-memory computation operation and receive a first clock signal, the first IMC processing tile generating a first computation output in response to execution of the in-memory computation operation;
a second IMC processing tile configured to store second computational weight data for an in-memory computation operation and configured to receive second feature data for that in-memory computation operation and receive a second clock signal, the second IMC processing tile generating a second computation output in response to execution of the in-memory computation operation;
a clock tree configured to generate the first and second clock signals, wherein the clock tree, in response to a random number, applies a randomized stagger to timing of the first and second clock signals; and
a binding circuit configured to match and bind the first and second computation outputs, wherein the binding circuit, in response to the random number, accounts for timing offset between the first and second computation outputs due to the randomized stagger to timing of the first and second clock signals.

2. The circuit of claim 1, wherein the randomized stagger applied to timing of the first and second clock signals comprises a phase shift between the first and second clock signals.

3. The circuit of claim 1, wherein the randomized stagger applied to timing of the first and second clock signals comprises a skipping of clock pulses among the first and second clock signals.

4. The circuit of claim 1, wherein the randomized stagger applied to timing of the first and second clock signals comprises an adding of clock pulses among the first and second clock signals.

5. The circuit of claim 1, further comprising a random number generator configured to generate the random number in connection with the execution of the in-memory compute operation.

6. The circuit of claim 1, wherein each of the first and second IMC processing tiles is implemented as one of an analog IMC processing tile or a digital IMC processing tile.

7. A method, comprising:
storing first computational weight data for an in-memory computation operation in a first in-memory computation (IMC) processing tile;
storing second computational weight data for an in-memory computation operation in a second IMC processing tile;
applying first feature data for the in-memory computation operation to the first IMC processing tile;
applying second feature data for the in-memory computation operation to the second IMC processing tile;
clocking the first IMC processing tile with a first clock signal to control execution of the in-memory computation operation by the first IMC processing tile to produce a first computation output;
clocking the second IMC processing tile with a second clock signal to control execution of the in-memory computation operation by the second IMC processing tile to produce a second computation output;
generating the first and second clock signals to have a randomized stagger in timing controlled by a random number; and
binding, in response to the random number, the first and second computation outputs, wherein binding includes matching to account for timing offsets between the first and second computation outputs due to the randomized stagger of the first and second clock signals.

8. The method of claim 7, wherein generating the first and second clock signals to have the randomized stagger comprises applying a phase shift between the first and second clock signals.

9. The method of claim 7, wherein generating the first and second clock signals to have the randomized stagger comprises a skipping of clock pulses among the first and second clock signals.

10. The method of claim 7, wherein generating the first and second clock signals to have the randomized stagger comprises an adding of clock pulses among the first and second clock signals.

11. The method of claim 7, wherein the in-memory computation operation performed by each of the first and second IMC processing tiles is one of an analog IMC processing operation or a digital IMC processing operation.

12. A circuit, comprising:
a first in-memory computation (IMC) processing tile group, wherein said first IMC processing tile group includes a first plurality of IMC processing tiles, each of the first plurality of IMC processing tiles configured to store computational weight data for an in-memory computation operation and configured to receive feature data for that in-memory computation operation, wherein the first plurality of IMC processing tiles of the first IMC processing tile group receive a first clock signal, the first plurality of IMC processing tiles generating first computation outputs in response to execution of the in-memory computation operation, the first IMC processing tile group further including a first binding circuit configured to bind the first computation outputs to generate a first tile group computation output;
a second IMC processing tile group, wherein said second IMC processing tile group includes a second plurality of IMC processing tiles, each of the second plurality of IMC processing tiles configured to store computational weight data for an in-memory computation operation and configured to receive feature data for that in-memory computation operation, wherein the second plurality of IMC processing tiles of the second IMC processing tile group receive a second clock signal, the second plurality of IMC processing tiles generating second computation outputs in response to execution of the in-memory computation operation, the second IMC processing tile group further including a second binding circuit configured to bind the second computation outputs to generate a second tile group computation output;
a clock tree configured to generate the first and second clock signals, wherein the clock tree, in response to a random number, applies a randomized stagger to timing of the first and second clock signals; and
a third binding circuit configured to match and bind the first and second tile group computation outputs, wherein the third binding circuit, in response to the random number, accounts for timing offset between the first and second tile group computation outputs due to the randomized stagger to timing of the first and second clock signals.

13. The circuit of claim 12, wherein the randomized stagger applied to timing of the first and second clock signals comprises a phase shift between the first and second clock signals.

14. The circuit of claim 12, wherein the randomized stagger applied to timing of the first and second clock signals comprises a skipping of clock pulses among the first and second clock signals.

15. The circuit of claim 12, wherein the randomized stagger applied to timing of the first and second clock signals comprises an adding of clock pulses among the first and second clock signals.

16. The circuit of claim 12, further comprising a random number generator configured to generate the random number in connection with the execution of the in-memory compute operation.

17. The circuit of claim 12, wherein processing tiles in each of the first and second pluralities of IMC processing tiles are implemented as one of analog IMC processing tiles or digital IMC processing tiles.

18. A method, comprising:
storing computational weight data for in-memory computation operations in a first plurality of in-memory computation (IMC) processing tiles arranged to form a first IMC processing tile group;
storing computational weight data for in-memory computation operations in a second plurality of IMC processing tiles arranged to form a second IMC processing tile group;
applying feature data for the in-memory computation operations to the first plurality of IMC processing tiles;
applying feature data for the in-memory computation operations to the second plurality of IMC processing tiles;
clocking the first plurality of IMC processing tiles within the first IMC processing tile group with a first clock signal to control execution of the in-memory computation operations by the first plurality of IMC processing tiles to produce first computation outputs;
binding the first computation outputs to generate a first tile group computation output;
clocking the second plurality of IMC processing tiles within the second IMC processing tile group with a second clock signal to control execution of the in-memory computation operations by the second plurality of IMC processing tiles to produce second computation outputs;
binding the second computation outputs to generate a second tile group computation output;
generating the first and second clock signals to have a randomized stagger in timing controlled by a random number; and
binding, in response to the random number, the first and second tile group computation outputs, wherein binding includes matching to account for timing offsets between the first and second tile group computation outputs due to the randomized stagger of the first and second clock signals.

19. The method of claim 18, wherein generating the first and second clock signals to have the randomized stagger comprises applying a phase shift between the first and second clock signals.

20. The method of claim 18, wherein generating the first and second clock signals to have the randomized stagger comprises a skipping of clock pulses among the first and second clock signals.

21. The method of claim 18, wherein generating the first and second clock signals to have the randomized stagger comprises an adding of clock pulses among the first and second clock signals.

22. The method of claim 18, wherein the in-memory computation operations performed by each of the first and second pluralities of IMC processing tiles are one of analog IMC processing operations or digital IMC processing operations.

23. An in-memory compute system, comprising:
in in-memory computation (IMC) processing tiles configured to store computational weight data for in-memory computation processing operations;
a clock tree configured to generate clock signals for application to the IMC processing tiles for controlling the execution of the in-memory computation processing operations;
wherein the clock tree, in response to a random number, applies a randomized stagger to timing of the clock signals;
wherein the randomized stagger in timing that is applied to IMC processing tile execution of in-memory computation processing operations produces a randomization to a power pattern for the in-memory compute system during processing operation in instances where the stored computational weight data is stationary and exhibits sparsity.

24. The system of claim 23, wherein the randomized stagger comprises a phase shift applied between the clock signals.

25. The system of claim 23, wherein the randomized stagger comprises a selective skipping of a clock pulse in the clock signals.

26. The system of claim 23, wherein the randomized stagger comprises a selected adding of a clock pulse in the clock signals.

27. The system of claim 23, further comprising a random number generator configured to generate the random number in connection with the execution of the in-memory compute processing operations.

28. The system of claim 23, wherein each IMC processing tile is implemented as one of an analog IMC processing tile or a digital IMC processing tile.
